(19) United States
(12) Patent Application Publication
(10) Pub. No.: US 2026/0221745 A1
(43) Pub. Date: Jul. 30, 2026

(54) RACK BUSBAR ASSEMBLY

(71) Applicant: BIZLINK INTERNATIONAL CORP., New Taipei City (TW)

(72) Inventors: Zengshi LAO, New Taipei City (TW); Haoran ZOU, New Taipei City (TW)

(21) Appl. No.: 19/457,169

(22) Filed: Jan. 23, 2026

(30) Foreign Application Priority Data
Jan. 24, 2025 (CN) 202510120742.6

(51) Int. Cl. H02G 5/10; H05K 7/14

(52) U.S. Cl. CPC H02G 5/10; H05K 7/1492

(57) ABSTRACT

A rack busbar assembly relates to the field of connector technology and includes a housing, busbars, an insulating member, thermal conductive elements, fastening members, and fasteners. Each busbar extends along a longitudinal direction and includes a shoulder, a waist, and a base, wherein the waist between the shoulder and the base forms a receiving slot. Each thermal conductive element is embedded in the receiving slot and is prevented from detaching by the fastening members and the fasteners. The insulating member is used to isolate the busbars to ensure electrical insulation and realize heat exchange. The busbars, the insulating member, and the fastening members are locked together by the fasteners. The assembly has a compact structure and is capable of providing efficient heat dissipation and stable power supply for a plurality of servers.

This application claims priority to China Application Serial Number 202510120742.6, filed January 24, 2025, which is herein incorporated by reference in its entirety.

### BACKGROUND

### Field of Invention

The present invention relates to the field of connector technology, and more particularly to a rack busbar assembly.

### Description of Related Art

U.S. Patent Application Publication No. 2024/0212887A1 discloses a busbar assembly for powering a server, including a housing, two busbars, and an intermediate insulating member. The busbars and the intermediate insulating member are fixed within the housing via a fastener passing through the housing, the busbars, and the intermediate insulating member.

However, similar busbars generate a significant amount of heat due to high current levels. If the heat cannot be dissipated rapidly, it may lead to busbar failure and an increased risk of malfunction. Conventional methods for heat dissipation involve using external fans on a rack or utilizing natural convection. Such designs exhibit low heat dissipation efficiency and struggle to satisfy cooling requirements as the current increases.

### SUMMARY

The main objective of the present invention is to propose a rack busbar assembly with improved heat dissipation performance and an improved design for fixing busbars.

According to one aspect of the present invention, a rack busbar assembly comprises a housing, two busbars disposed within the housing and extending along a longitudinal direction, an insulating member disposed between the two busbars, two thermal conductive elements, at least one fastening member, and at least one fastener. Each of the two busbars comprises a shoulder, a waist, and a base arranged along a height direction, wherein a thickness of the waist in a width direction is less than a thickness of the shoulder and a thickness of the base, thereby defining a receiving slot between the shoulder and the base. The two thermal conductive elements are respectively embedded in the receiving slot of each of the two busbars. The at least one fastening member comprises a horizontal portion and a vertical portion connected to the horizontal portion, wherein the vertical portion at least partially covers an opening of the receiving slot to retain the thermal conductive element. The at least one fastener passes through the two busbars and the insulating member to secure the two busbars and the insulating member in a fixed relative position, wherein the fastener simultaneously passes through the horizontal portion of the fastening member.

According to another aspect of the present invention, a rack busbar assembly comprises a housing, a first busbar defining a receiving slot, a second busbar, a thermal conductive element embedded in the receiving slot, an upper fastening member, a lower fastening member, and a fastener. The upper fastening member is fixed to the first busbar and comprises a cantilever structure at least partially covering the receiving slot to retain the thermal conductive element. The lower fastening member is fixed to the first busbar and comprises a cantilever structure at least partially covering the receiving slot to retain the thermal conductive element. The fastener passes through the first busbar and the second busbar, and simultaneously passes through a portion of the upper fastening member or the lower fastening member to secure the upper or lower fastening member.

The technical solution of the rack busbar assembly proposed by the present invention uses various fastening members to fix the thermal conductive elements in the receiving slots of the two busbars and prevents them from sliding, thereby ensuring that the busbars can be properly fixed in the housing. Furthermore, the embedded design of the thermal conductive element allows it to be in close contact with the busbar, enabling rapid conduction of heat generated by the busbar during operation to the thermal conductive element and efficient dissipation of heat from the heat source, resulting in higher heat dissipation efficiency.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic view showing an overall structure of a rack busbar assembly according to an embodiment of the present invention;

FIG. 2 is a schematic view showing a relative relationship between a housing and a cover plate in FIG. 1;

FIG. 3 is a schematic view of FIG. 1 with the housing omitted;

FIG. 4 is an enlarged schematic view of a head portion in FIG. 3;

FIG. 5 is a partial cross-sectional view taken along line A-A in FIG. 4;

FIG. 6 is a partial cross-sectional view taken along line B-B in FIG. 4;

FIG. 7 is a schematic view showing an appearance of a thermal conductive element in a thermal conductive element group in FIG. 1; and

FIG. 8 is a schematic view of the thermal conductive element in the thermal conductive element group in FIG. 1 with a portion of an outer surface removed.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The technical solutions in the embodiments of the present invention will be described clearly and completely below with reference to the accompanying drawings in the embodiments of the present invention. It is apparent that the described embodiments are only a portion of the embodiments of the present invention, rather than all of the embodiments. Based on the embodiments in the present invention, all other embodiments obtained by those of ordinary skill in the art without creative effort shall fall within the scope of protection of the present invention.

It should be noted that if directional indicators (such as up, down, left, right, front, back, etc.) are involved in the embodiments of the present invention, the directional indicators are only used to explain the relative positional relationship, movement, etc., between various components in a specific posture. If the specific posture changes, the directional indicators will change accordingly.

In addition, if descriptions involving "first," "second," etc., are involved in the embodiments of the present invention, the descriptions of "first," "second," etc., are for descriptive purposes only and should not be understood as indicating or implying their relative importance or implicitly indicating the number of indicated technical features. Thus, a feature defined by "first" or "second" may explicitly or implicitly include at least one such feature. Furthermore, if "and/or" appears in the text, its meaning includes three parallel solutions; taking "A and/or B" as an example, it includes solution A, solution B, or a solution where both A and B are satisfied simultaneously. In addition, the technical solutions between various embodiments can be combined with each other, provided that such combinations are based on what can be realized by those of ordinary skill in the art. When a combination of technical solutions is contradictory or impossible to achieve, such a combination should be considered non-existent and is not within the scope of protection claimed by the present invention. If the present invention mentions "A includes/comprises B," unless explicitly excluded or not allowed by the context, the inclusion or comprehension therein means that A includes one or more B.

It should be noted that the drawings of the present invention are drawn to scale, and the dimensional proportions and relative positions of various components should be considered as part of the disclosure.

The present invention provides a rack busbar assembly used for simultaneously powering a plurality of servers. By the following design, it can be ensured that the busbars are stably fixed in the housing to ensure proper operation of the device.

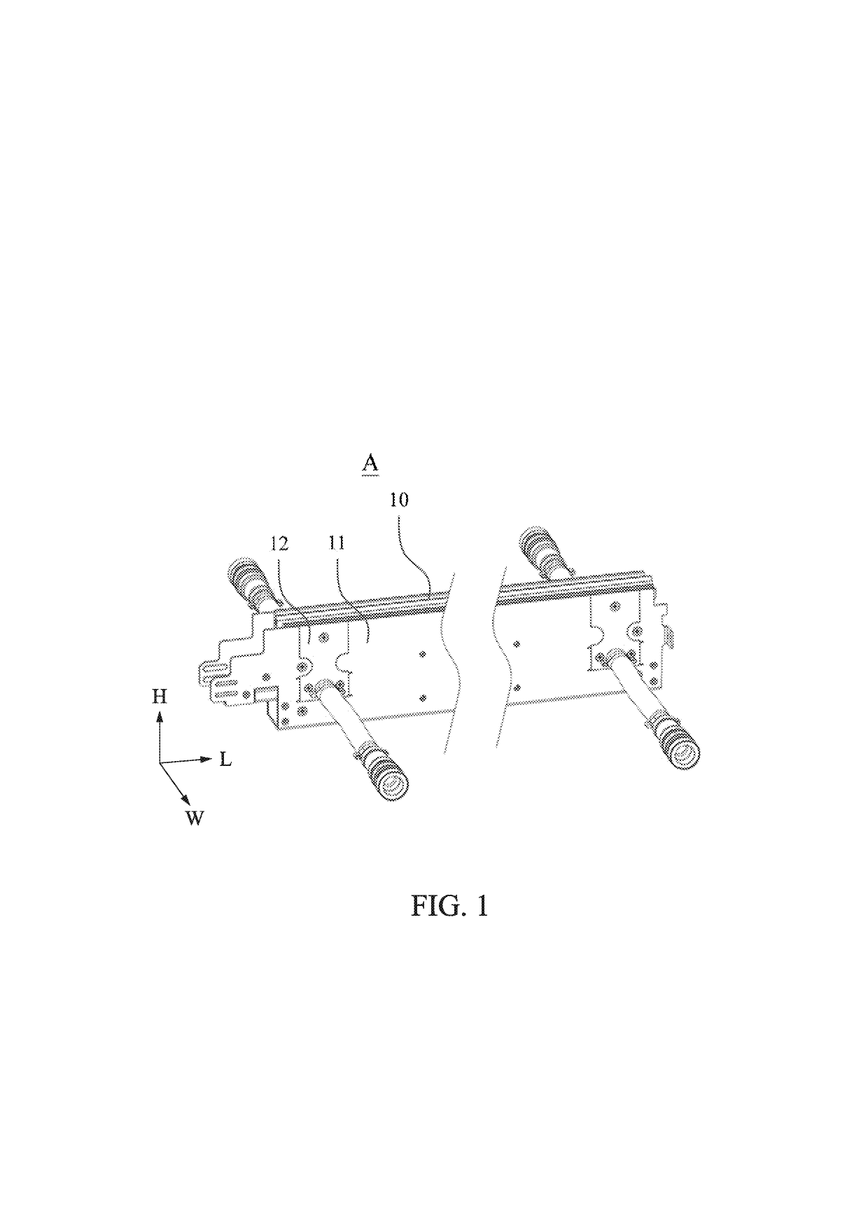

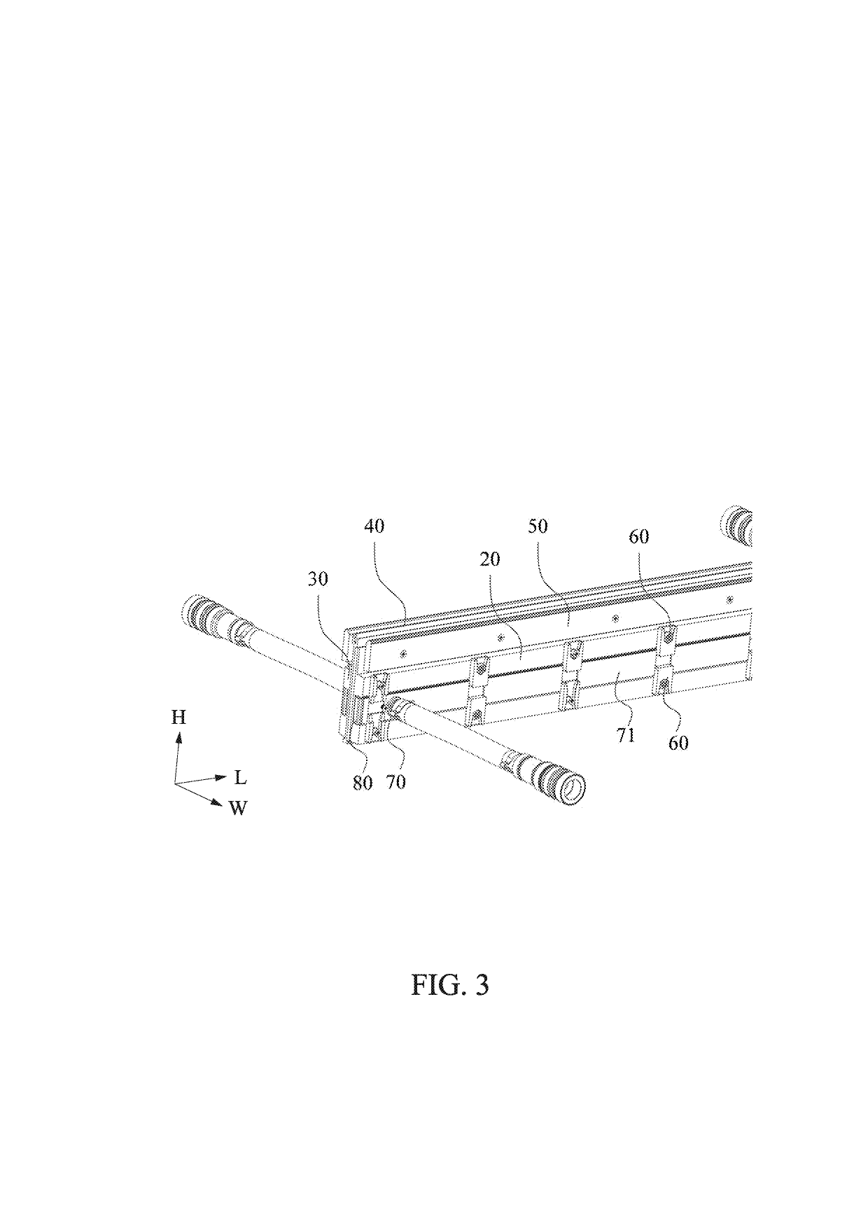

The design of the rack busbar assembly of the present invention will be explained below with an embodiment. Referring to FIG. 1 and FIG. 3, the rack busbar assembly A includes many parts, among which the main parts are a housing 10, two busbars 20, 30, an insulating member 40, two grounding bars 50, a plurality of fastening members 60, two thermal conductive element groups 70, a thermal conductive insulating material layer 80, and a plurality of parts used for fixing, such as fasteners 90 (e.g., screws and nuts of different lengths).

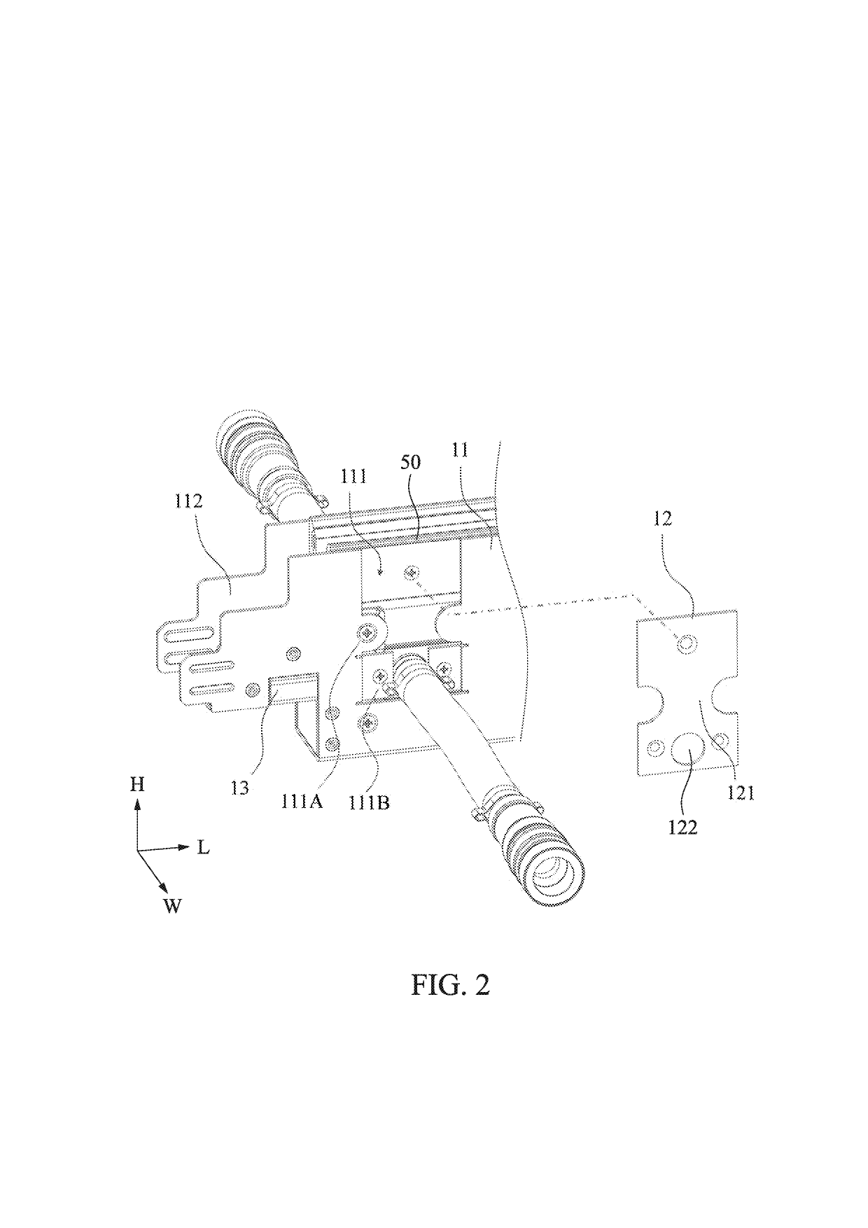

The design of the housing 10 is described below. Referring to FIG. 2, the housing 10 generally comprises a main body portion 11 and cover plates 12. The main body portion 11 of the housing 10 includes a metal frame having a substantially U-shape cross-section. The housing 10 defines a longitudinal direction L along its length, a width direction W along its width, and a height direction H along its height.

At the front end and rear end of the main body portion 11 of the housing 10 in the longitudinal direction L, the outer surfaces in the width direction W are respectively provided with lateral openings 111 extending downward from the upper edge in the height direction H. In an embodiment, there are four lateral openings 111 in total, with two of the lateral openings 111 located at the front end and the other two lateral openings 111 located at the rear end of the main body portion 11. The middle portion of each lateral opening 111 in the height direction H is respectively provided with a semi-circular protrusion 111A protruding into the lateral opening 111 along the longitudinal direction L. The protrusion 111Aincludes at least one through-hole for components such as screws to pass through. In addition, a baffle 111B, which is recessed via two right-angle bends toward the inner side in the width direction W, is provided below the semi-circular protrusion 111A in the height direction H. Through-holes are provided on the baffle 111B for components such as screws to pass through to fix the cover plate 12 to the outer side in the width direction W thereof. The surface where the through-holes of the baffle 111B are located extends from a periphery of the lateral opening 111 of the housing 10 through two right-angle bends and is substantially parallel to the cover plate 12. In an embodiment, the semi-circular protrusion 111A and the baffle 111B are offset from each other along the width direction W. Specifically, the baffle 111B is recessed inward relative to the semi-circular protrusion 111A, thereby defining a space for receiving the cover plate 12.

In addition, the cover plate 12 is embedded in each lateral opening 111, and the shape of the cover plate 12 matches each lateral opening 111 to close the lateral opening 111. The middle portion of the cover plate 12 in the height direction H is provided with a semi-circular notch 121 having a shape complementary to the semi-circular protrusion 111A. The upper portion of the cover plate 12 in the height direction H is provided with a locking hole for components such as screws to pass through, used for simultaneously fixing the grounding bar 50 to the inner side of the main body portion 11 in the width direction W. The lower portion of the cover plate 12 in the height direction H includes a wider tube hole 122 for pipelines to pass through, and a plurality of locking holes are respectively provided on both sides of the tube hole 122. After the cover plate 12 is embedded in the lateral opening 111, its inner surface in the width direction W abuts against the baffle 111B and is fixed thereto via screws, and the outer surface of the cover plate 12 in the width direction W is substantially flush with the outer surface of the main body portion 11 in the width direction W.

Both the front and rear ends of the main body portion 11 of the housing 10 in the longitudinal direction L have fixing arm portions 112 further extending along the longitudinal direction L, and a support plate 13 is connected to the lower opening between the two fixing arm portions 112 in the height direction H. Both the fixing arm portions 112 and the support plate 13 are respectively used for fixing with external structures.

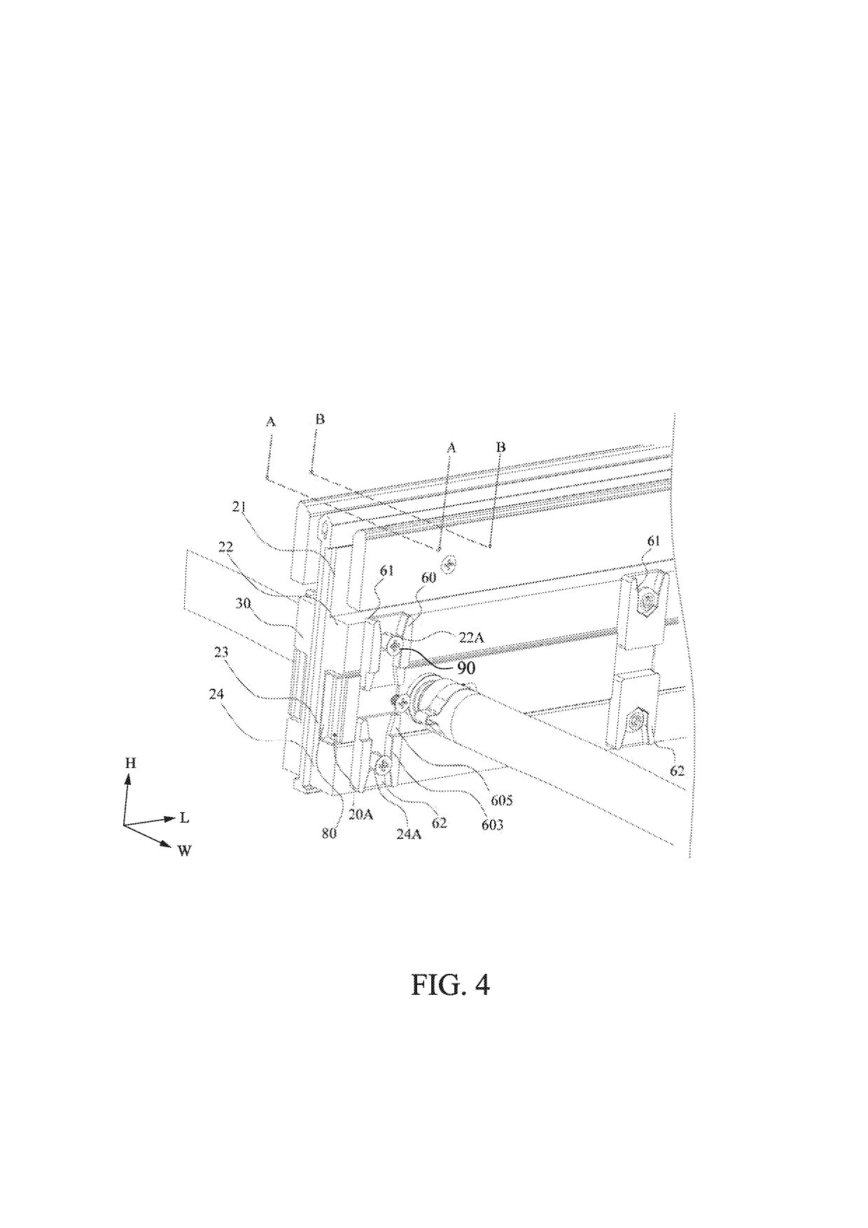

The design of the busbar 20 is explained below. Referring to FIG. 3 and FIG. 4, it can be seen from the figures that the busbar 20 (also referred to as a first busbar) is integrally formed. The polarity of the busbar 20 is opposite to that of the busbar 30. The busbar 20 has a head portion 21, a shoulder 22, a waist 23, and a base 24 sequentially connected along the height direction H. Each of the head portion 21, the shoulder 22, the waist 23, and the base 24 is in a rectangular bar shape, and their inner surfaces in the width direction W collectively form an inner coplanar surface to abut against the surface of the insulating member 40. The thickness of the waist 23 in the width direction W is less than the thicknesses of the shoulder 22 and the base 24, so that the shoulder 22, the waist 23, and the base 24 together define and form a rectangular receiving slot 20A extending along the longitudinal direction L.

The side surfaces of the shoulder 22 and the base 24 in the width direction W are respectively provided with a plurality of through-holes penetrating through their inner and outer surfaces, referred to as fixing holes 22A, 24A. The fixing holes 22A, 24A are used for embedding the fastening members 60 or components such as screws. The fixing hole 22A located at the shoulder 22 may be referred to as an upper fixing hole 22A, and the fixing hole 24A located at the base may be referred to as a lower fixing hole 24A.

The head portion 21 and the shoulder 22 define an L-shaped accommodation space. The grounding bar 50 is fixed to the housing 10 and is suspended within the L-shaped accommodation space.

The design of the busbar 30 is explained below. The design of the busbar 30 substantially corresponds to and is identical to that of the busbar 20, and is arranged in a mirror-image manner.

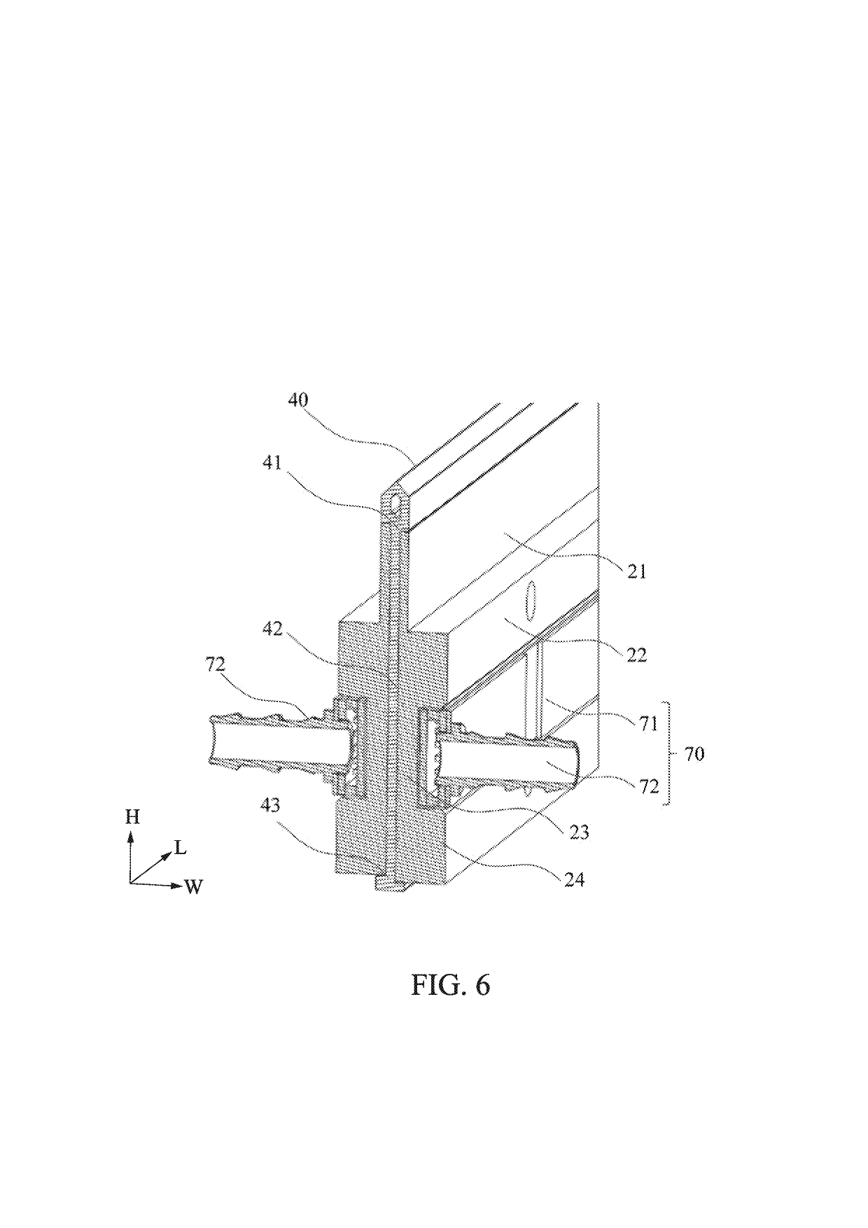

The design of the insulating member 40 is explained below. Referring to FIG. 6, the insulating member 40 is integrally formed of a high-resistance material, and most of it extends uniformly along the longitudinal direction L. The term "uniformly" means that the shape of each cross-section along the longitudinal direction L is substantially the same. The insulating member 40 has a top portion 41, a middle portion 42, and a base portion 43 sequentially from top to bottom. The top portion 41 is a hollow tubular shape extending along the longitudinal direction L, and its cross-sectional shape is a gable-roof shape. The lower edge surface of one side of the top portion 41 in the width direction W is higher in the height direction H, while the other side in the width direction W is lower, so that the two busbars 20, 30 form a displacement and a height difference. The middle portion 42 is a vertical plate used to isolate the busbar 20 and the busbar 30 to prevent a short circuit between the two. In the width direction W, the left and right sides of the base portion 43 respectively extend toward both sides to contact and support the busbar 20 and the busbar 30, respectively. Similarly, in the width direction W, the left side of the base portion 43 is thicker while the right side is thinner, allowing the busbar 20 and the busbar 30 to form a displacement and a height difference. Referring to FIG. 4, the length of the insulating member 40 in the longitudinal direction L is greater than the lengths of the busbars 20, 30; that is, parts of its front and rear ends in the longitudinal direction L will protrude from the two busbars 20, 30.

The design of the grounding bar 50 is explained below. Referring to FIG. 2, the two grounding bars 50 can be made of a metal material and are fixed to the inner sides of both sides of the main body portion 11 by a plurality of screws passing through the cover plate 12 and the main body portion 11. In an embodiment, this configuration achieves a "multi-in-one" objective, significantly reduces the number of screws required for rack assembly, lowers manufacturing costs, and shortens maintenance time.

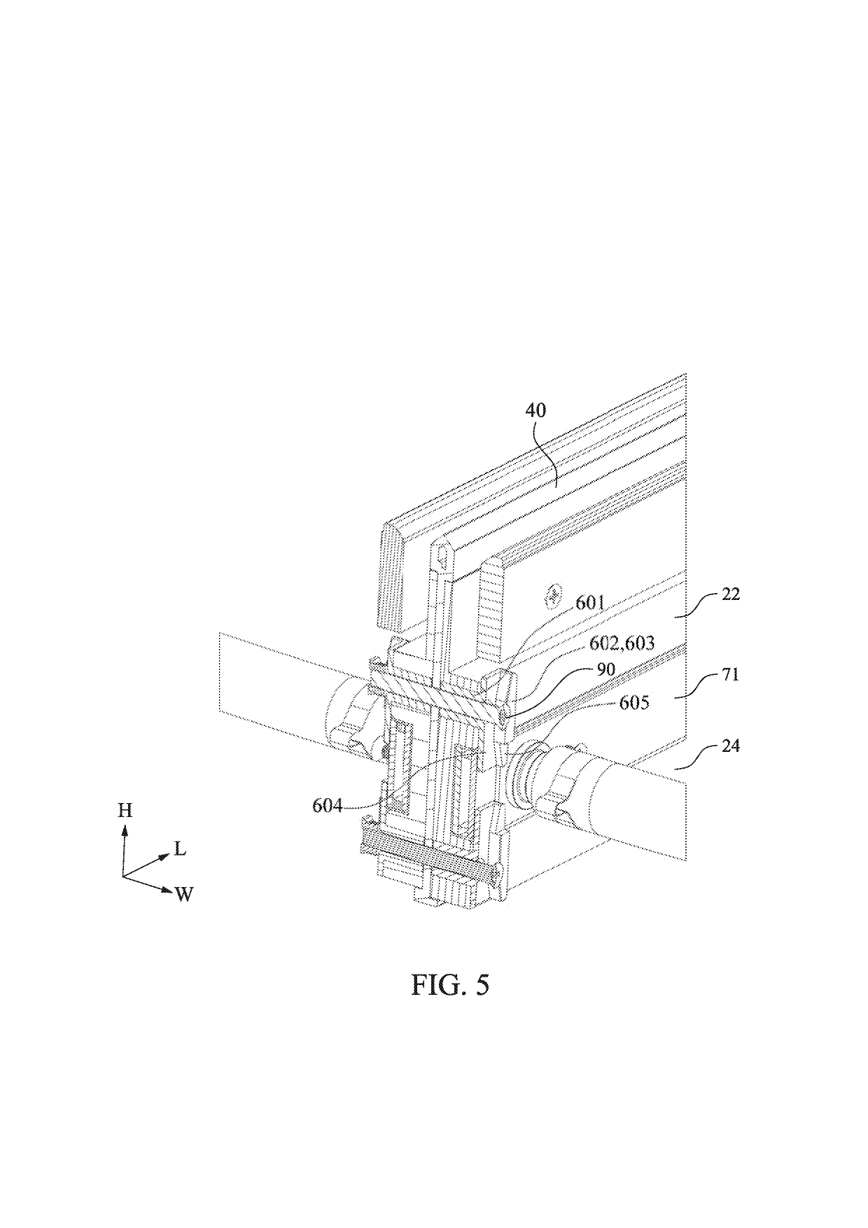

The design of the fastening member 60 is explained below. Referring to the design in FIG. 4, it can be seen that a plurality of fastening members 60 are fixed to the upper fixing holes 22A of the shoulders 22 and the lower fixing holes 24A of the bases 24 of the busbars 20, 30 via components such as screws. The fastening member 60 fixed to the shoulder can be referred to as an upper fastening member 61, and the fastening member 60 fixed to the base 24 can be referred to as a lower fastening member 62. Referring to FIG. 5, the fastening member 60 is integrally formed of an insulating material and can be roughly divided into two parts: a horizontal portion 601 and a vertical portion 602. Referring to FIG. 5, the horizontal portion 601 has a hollow conduit penetrating through two side surfaces of the busbar 20 in the width direction W, allowing components such as screws to enter and pass through.

Specifically, the rack busbar assembly of the present invention achieves interconnected securing (or fixing) of the busbars 20, 30 and the insulating member 40 by passing at least one fastener 90 (e.g., a screw) through hollow conduits thereof. Particularly, the fastener 90 simultaneously passes through the horizontal portion 601 of the fastening member 60 during the locking process. In an embodiment, by this design, the assembly process is simplified via a 'multi-in-one' locking path, while ensuring that the thermal conductive elements 71 fit tightly and stably within the receiving slots 20A, thereby enhancing structural reliability and heat conduction efficiency. Furthermore, this locking structure ensures that various components maintain excellent geometric stability under stress, effectively preventing displacement of the thermal conductive element 71 due to vibration or thermal expansion and contraction.

The vertical portion 602 is disposed perpendicular to the horizontal portion 601, and the inner surface of the vertical portion 602 of each fastening member 60 in the width direction W flatly abuts against the outer side surfaces of the shoulder 22 and the base 24 in the width direction W. Taking the upper fastening member 61 at the upper fixing hole 22A as an example, its upper and lower sides in the height direction H respectively extend outward along the height direction H and form a cantilever structure to at least partially cover the receiving slot 20A. Structurally, the term 'cantilever structure' as used herein refers to a configuration where a portion of the vertical portion 602 extends outwardly along the height direction H from its connection with the horizontal portion 601. This extending portion is supported at its proximal end and projects over the opening of the receiving slot 20A, characterized in that its distal end is substantially unsupported from underneath to allow it to retain the thermal conductive element 71. The cantilever structure is used to block or contact the thermal conductive element 71 in the thermal conductive element group 70, thereby preventing the thermal conductive element 71 from detaching from the receiving slot 20A in the width direction W. The lower fastening member 63 may have a similar cantilever structure extending upward.

More specifically, the horizontal portion 601 is used for the fastener 90 to pass through to achieve positioning, while the vertical portion 602 is stably disposed at the opening of the receiving slot 20A by the locking action to block the thermal conductive element 71 from detaching from the receiving slot 20A.

In one embodiment, the fastening member 60 is made of an insulating material. As shown in FIG. 5, the horizontal portion 601 is interposed between the fastener 90 and the busbars 20, 30 to electrically isolate the fastener 90 from the busbars 20, 30. This configuration prevents an electrical connection between the two busbars 20, 30 through the metallic fastener 90.

Referring to FIG. 5, a portion of the upper fastening member 61 also protrudes upward from the shoulder 22 in the height direction H and forms a cantilever structure. In addition, the design of the fastening member 60 at the lower fixing hole 24A is substantially the same as the aforementioned design, also having a portion that forms a cantilever structure to prevent the thermal conductive element 71 from detaching from the receiving slot 20A in the width direction W. In an embodiment, the positions of the upper fixing hole 22A and the lower fixing hole 24A are the same in the longitudinal direction L; thus, upper fastening member 61 and the lower fastening member 62 are vertically aligned in the height direction H to form a gap therebetween, through which a portion of the thermal conductive element 71 is exposed. In an embodiment, this configuration provides a space for visual confirmation of the assembly status, increases the heat dissipation area of the thermal conductive element 71 in contact with air, and maintains the lateral physical limiting function of the vertical portion for the thermal conductive element 71. The left and right edges of the vertical portion 602 of each fastening member 60 in the longitudinal direction L can abut against the walls of the retaining grooves 713 on the surface of the thermal conductive element 71 to prevent the thermal conductive element 71 from sliding along the longitudinal direction L. In an embodiment, this configuration effectively locks the longitudinal position of the thermal conductive element 71 and prevents it from shifting during vertical installation or in an environment with operating vibrations.

The design of the outer surface of the fastening member 60 in the width direction W varies depending on its position. The following uses the fastening member 60 located at the cover plate 12 or the lateral opening 111 and the remaining fastening members 60 not located at the lateral opening 111 as examples for explanation.

Referring to FIG. 5, the fastening member 60 corresponding to the lateral opening 111 includes two blocks 603 disposed on an outer surface in the width direction W. The two blocks 603 are spaced apart in the longitudinal direction L to define a guiding groove 604 therebetween. Along the height direction H from top to bottom, the guiding groove 604 sequentially tapers, maintains width in the middle, and widens at the lower section. Structurally, the guiding groove 604 includes a tapered segment, a constant-width segment, and a flared segment corresponding to the variation in width from top to bottom. In an embodiment, this configuration guides the fastener 90 to cut into position accurately and rapidly. The hollow conduit of the fastening member 60 is located at the middle section. The two blocks 603 are bounded by the portion cantilevered over the rectangular receiving slot 20A, and a stepped notch 605 is formed at the lower section. That is, the thickness of the cantilevered portion of the block 603 is thinner but still protrudes relative to the bottom of the guiding groove 604. In this way, the space reserved by the stepped notch 605 can accommodate the baffle 111B which is recessed after being bent toward the inner side in the width direction W, thereby avoiding geometric interference between the fastening member 60 and the housing 10. In an embodiment, this configuration maximizes internal space utilization and eliminates geometric interference between components, while maintaining a flat appearance of the housing and ensuring that the assembly can be smoothly installed in narrow rack spaces. In contrast, for the fastening members 60 not located at the lateral opening 111, the upper section tapers downward to merge at the middle section. The lower section of these fastening members 60 maintains a uniform thickness that is consistent with the thickness of the block 603 at the upper section, thereby forming a continuous cantilever structure without the guiding groove 604 or the stepped notch 605.

Referring to FIG. 5, both the busbar 30 and the insulating member 40 are provided with hollow conduits penetrating through two side surfaces in the width direction W, and the hollow conduits of the busbar 20, the busbar 30, and the insulating member 40 are aligned. During assembly, a fastener 90 can be used to pass through the hollow conduits of the busbar 20, the busbar 30, and the insulating member 40 and be connected via a nut to clamp the two busbars 20, 30 therein.

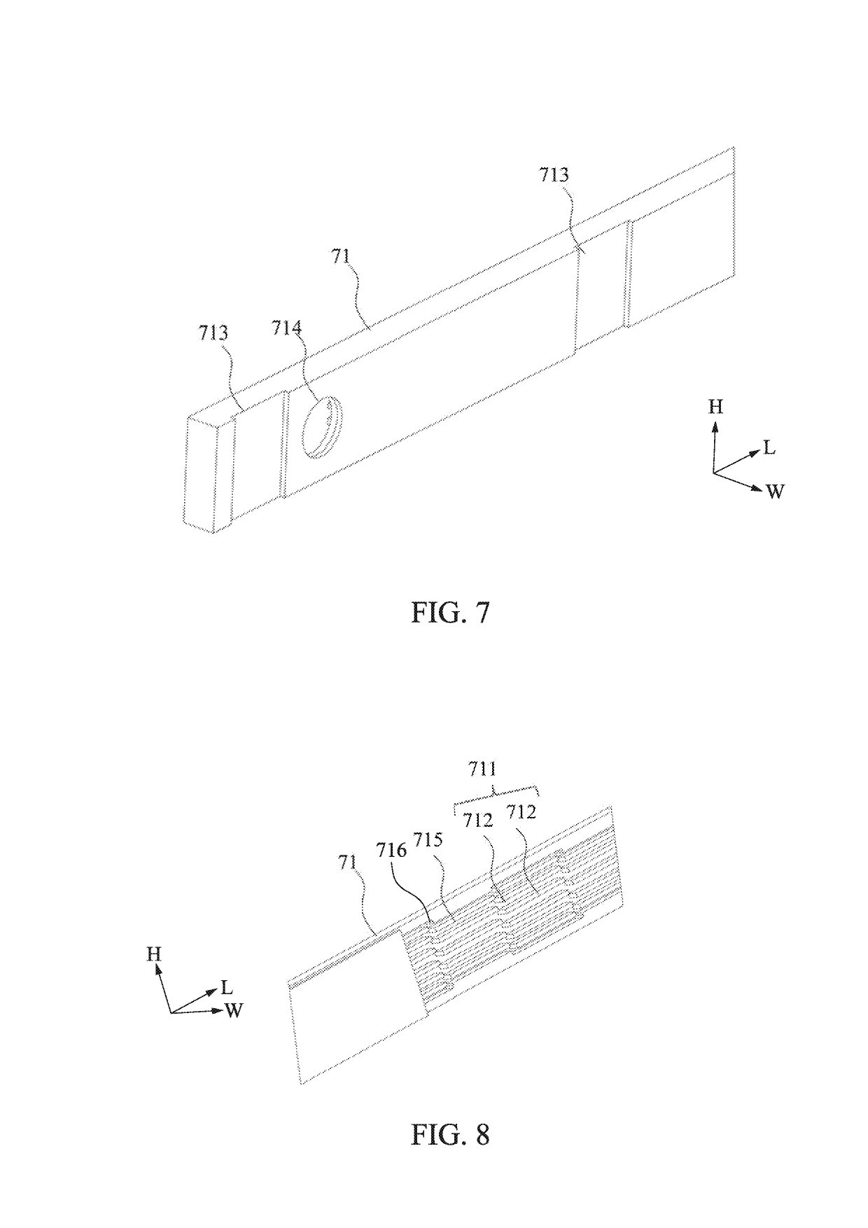

The design of the two thermal conductive element groups 70 is explained below. Referring to FIG. 6 and FIG. 7, the two thermal conductive element groups 70 respectively include a thermal conductive element 71 and two nozzle-shaped connectors 72 at both front and rear ends in the longitudinal direction L.

The thermal conductive elements 71 are respectively liquid-cooled plates extending along the longitudinal direction L. However, each thermal conductive element 71 can also be a heat pipe or a thermal conductive block (e.g., solid metal body) with high thermal conductivity. In an embodiment where the thermal conductive element 71 is configured as a liquid-cooled plate or a thermal conductive block, the interior thereof defines a main flow channel 715 and a plurality of fins 712 for heat exchange. On an outer side plate of the thermal conductive element 71 in the width direction W, a plurality of cut shallow grooves, or retaining grooves 713, are provided. The retaining grooves 713 are disposed corresponding to the fastening members 60. The fastening members 60 are embedded in the retaining grooves 713 so that their groove walls can abut against the side edges of the fastening members 60, thereby preventing the thermal conductive elements 71 from sliding along the longitudinal direction L in the receiving slots 20A. The formation of the retaining grooves 713 can be achieved by the aforementioned cutting, or by pasting blocks of thermally conductive or insulating material on the surface of the thermal conductive element 71 to form the retaining grooves 713 therebetween, thereby reducing costs.

Referring to FIG. 8, the thermal conductive element 71 has a main flow channel 715 extending along the longitudinal direction L. If the outer side plate of the thermal conductive element 71 in the width direction W is opened, it can be seen that the main flow channel 715 is composed of a plurality of wide flow sections and narrow flow sections connected and arranged alternately. Specifically, these wide flow sections and narrow flow sections are fluidly communicating with each other, thereby allowing the cooling fluid to flow continuously through the main flow channel 715 while undergoing pressure and velocity changes to enhance heat exchange. The main flow channel 715 communicates with external pipelines only through inlet and outlet ports 714 at both front and rear ends in the longitudinal direction L. A plurality of fin groups 711 are formed between an inner side plate and the outer side plate of the thermal conductive element 71 in the width direction W. Each fin group 711 includes a plurality of fins 712, and each fin 712 and another fin 712 or an internal surface of the thermal conductive element 71 respectively define a smaller sub-flow channel.

Furthermore, the flow channel corners, specifically where the main flow channel 715 transitions from a wide section to a narrow section, are provided with a curved guide structure 716. Structurally, the curved guide structure 716 is formed by a transition surface (such as a rounded fillet or a chamfered bevel) extending between the wall surfaces of the sections.

In an embodiment, this curved guide structure 716 contributes to several technical advantages. For instance, it helps to reduce flow resistance and pressure drop by guiding the fluid smoothly through section transitions, minimizing flow separation and ineffective vortices compared to right-angled turns. Additionally, the design is intended to improve heat exchange efficiency by reducing flow dead zones where bubbles or impurities might accumulate, ensuring that the cooling fluid uniformly covers the fin surfaces of the fins 712. Furthermore, the transition surface helps to reduce stress concentrations caused by fluid pressure, potentially enhancing the structural durability of the thermal conductive element 71 and mitigating erosion-corrosion at the flow edges.

In an embodiment, an inner surface of the outer side plate of the thermal conductive element 71 in the width direction W can be physically connected (e.g., combined through welding or an integral molding process) with the fins 712 to strengthen the heat conduction path. In another embodiment, the inner surface of the outer side plate of the thermal conductive element 71 in the width direction W may also not be connected to the fins 712 (i.e., maintaining a tiny gap therebetween) to facilitate assembly or allow for differences in thermal expansion between different materials. Furthermore, regarding the geometric arrangement of the fins 712, a surface of the fin 712 on the longitudinal direction L side (i.e., the surface facing the fluid inflow direction) can be disposed perpendicular to a bottom surface of the main flow channel 715; alternatively, the surface of the fin 712 on the longitudinal direction L side can also maintain an oblique angle (i.e., inclined arrangement) relative to the bottom surface of the main flow channel 715, thereby guiding the fluid to deflect in a specific direction or generate more intense high-temperature boundary layer disturbances.

An outlet of each sub-flow channel in the fin group 711 is aligned with a surface of a downstream fin 712 along the longitudinal direction L. Such an arrangement directs fluid exiting the sub-flow channel to impinge on the surface of the downstream fin 712, thereby altering the flow direction and dissipating kinetic energy. In an embodiment, the impact of the fluid against the downstream fins 712 promotes turbulent flow and increases the residence time of the coolant on the fin surfaces, thereby enhancing the overall heat dissipation performance.

A transversely disposed connector 72 is provided on a surface of the thermal conductive element 71 in the width direction W respectively at the front and rear ends in the longitudinal direction L. One end of the connector 72 is welded to the inlet/outlet port 714 of the thermal conductive element 71, and the other side communicates with a pipeline via a snap ring. In use, the connector 72 can obtain cooling fluid from an external pipeline and input it into the main flow channel 715 inside the thermal conductive element 71.

The design of the thermal conductive insulating material layer 80 is explained below. Referring to FIG. 4, the thermal conductive insulating material layer 80 is made of a material that is electrically insulating and has good thermal conductivity, such as a thermal silicone sheet. However, if necessary, it may also be formed by a thermal grease or a combination of multiple material layers respectively having thermal conductive and insulating properties. The thermal conductive insulating material layer 80 is disposed between the busbars 20, 30 and the respective thermal conductive elements 71 for conducting thermal energy of the busbars to the surface of the thermal conductive element 71 while ensuring that the thermal conductive elements 71 and the busbars 20, 30 are electrically insulated to each other. The thermal conductive insulating material layer 80 has C-shaped-section and substantially covers the inner surfaces of the receiving slot 20A. In an embodiment, this configuration is designed to provide electrical insulation between the high-current path and the thermal conductive element 71, thereby preventing current leakage.

In application, cooling fluid enters the internal main flow channel 715 from one end of the thermal conductive element 71 through the connector 72 from a pipeline. After the cooling fluid flows along the longitudinal direction L and takes away thermal energy from the busbar 20, it leaves from the connector at the other end of the thermal conductive element 71 to complete the cooling process.

The above are only exemplary embodiments of the present invention and do not limit the scope of the patent of the present invention. Any equivalent structural transformations made under the technical concept of the present invention using the contents of the description and drawings of the present invention, or direct/indirect applications in other related technical fields, are included in the scope of patent protection of the present invention.

What is claimed is:

1. A rack busbar assembly, comprising:
a housing;
two busbars disposed within the housing and extending along a longitudinal direction, each of the two busbars comprising a shoulder, a waist, and a base arranged along a height direction, wherein a thickness of the waist in a width direction is less than a thickness of the shoulder and a thickness of the base, thereby defining a receiving slot between the shoulder and the base;
an insulating member disposed between the two busbars;
two thermal conductive elements respectively embedded within the receiving slot of each of the two busbars;
at least one fastening member comprising a horizontal portion and a vertical portion connected to the horizontal portion, the vertical portion at least partially covering an opening of the receiving slot to retain the thermal conductive element; and
at least one fastener passing through the two busbars and the insulating member to secure the two busbars and the insulating member in a fixed relative position, wherein the fastener simultaneously passes through the horizontal portion of the fastening member.

2. The rack busbar assembly of claim 1, wherein the horizontal portion of the fastening member is embedded in a fixing hole of the corresponding shoulder or base.

3. The rack busbar assembly of claim 2, wherein the vertical portion of the fastening member abuts against an outer surface of the shoulder or the base.

4. The rack busbar assembly of claim 1, wherein the at least one fastening member comprises an upper fastening member and a lower fastening member vertically aligned along the height direction, a gap being maintained between the upper fastening member and the lower fastening member to expose a portion of a surface of the thermal conductive element.

5. The rack busbar assembly of claim 1, wherein a surface of the thermal conductive element is provided with a retaining groove, and an edge of the vertical portion of the fastening member abuts against a wall of the retaining groove, thereby preventing the thermal conductive element from sliding along the longitudinal direction.

6. The rack busbar assembly of claim 1, wherein the housing comprises at least one lateral opening and a baffle extending from a periphery of the at least one lateral opening, the baffle being recessed toward an inner side of the housing in the width direction.

7. The rack busbar assembly of claim 6, further comprising a cover plate, wherein the cover plate is locked to the baffle, and an outer surface of the cover plate is flush with an outer surface of the housing.

8. The rack busbar assembly of claim 6, wherein the fastening member defines a stepped notch on an outer surface of the vertical portion, and a space reserved by the stepped notch accommodates the baffle.

9. The rack busbar assembly of claim 1, wherein an outer surface of the fastening member is provided with a guiding groove extending along a height direction, and the guiding groove having a width that varies from top to bottom and includes a tapered segment, a constant-width segment, and a flared segment.

10. The rack busbar assembly of claim 1, wherein an interior of the thermal conductive element comprises a main flow channel, the main flow channel comprising a plurality of wide sections and narrow sections alternately arranged and fluidly communicating with each other.

11. The rack busbar assembly of claim 10, wherein a plurality of fins are disposed in the main flow channel, each pair of adjacent fins defining a sub-flow channel therebetween, and
wherein an outlet of each sub-flow channel is aligned with a surface of a downstream fin along the longitudinal direction.

12. The rack busbar assembly of claim 11, wherein a transition surface extending from a wall surface of the main flow channel to a wall surface of the narrow section forms a curved guide structure.

13. The rack busbar assembly of claim 1, wherein each of the two busbars comprises a head portion; the head portion and the shoulder form an L-shaped accommodation space; and the rack busbar assembly further comprises a grounding bar fixed to the housing and suspended within the L-shaped accommodation space.

14. The rack busbar assembly of claim 1, further comprising a thermal conductive insulating material layer, the thermal conductive insulating material layer having a C-shaped-section and substantially covering inner surfaces of the receiving slot.

15. A rack busbar assembly, comprising:
a housing;
a first busbar defining a receiving slot;
a second busbar;
a thermal conductive element embedded in the receiving slot;
an upper fastening member fixed to the first busbar and comprising a cantilever structure at least partially covering a portion of the receiving slot to retain the thermal conductive element;
a lower fastening member fixed to the first busbar and comprising a cantilever structure at least partially covering another portion of the receiving slot to retain the thermal conductive element; and
a fastener passing through the first busbar and the second busbar, and simultaneously passing through a portion of the upper fastening member or the lower fastening member to secure the upper or lower fastening member.

16. The rack busbar assembly of claim 15, further comprising an insulating member disposed between the first busbar and the second busbar, wherein the first busbar, the second busbar and the insulating member are simultaneously passed through by the fastener.

17. The rack busbar assembly of claim 15, wherein the upper fastening member and the lower fastening member are vertically aligned along a height direction, and a gap is maintained between the upper fastening member and the lower fastening member to expose a portion of a surface of the thermal conductive element.

18. The rack busbar assembly of claim 15, wherein the housing is provided with a recessed baffle; and the upper fastening member or the lower fastening member comprises a stepped notch to accommodate the baffle.

19. The rack busbar assembly of claim 18, further comprising a cover plate locked to the baffle, wherein an outer surface of the cover plate is flush with an outer surface of the housing.

20. The rack busbar assembly of claim 19, further comprising:
a grounding bar, wherein an upper portion of the cover plate in a height direction is provided with a locking hole configured for a screw to pass through to fix the grounding bar and the cover plate together to the housing.
